(19) United States
(12) Patent Application Publication
(10) Pub. No.: US 2021/0068320 A1
(43) Pub. Date: Mar. 4, 2021

(54) SHIELDING FOR SUPERCONDUCTING DEVICES

(71) Applicant: International Business Machines Corporation, Armonk, NY (US)

(72) Inventors: Daniela Florentina Bogorin, Syracuse, NY (US); Sean Hart, Tarrytown, NY (US); Patryk Gumann, Tarrytown, NY (US); Nicholas Torleiv Bronn, Long Island City, NY (US); Salvatore Bernardo Olivadese, Stamford, CT (US); Oblesh Jinka, Stamford, CT (US)

(21) Appl. No.: 16/556,996

(22) Filed: Aug. 30, 2019

(51) Int. Cl. H05K 9/00; H01L 39/04; F17C 13/00

(52) U.S. Cl. CPC H05K 9/0077; H05K 9/0088; H01L 39/04; F17C 2203/0387; F17C 2203/0631; F17C 2203/0308; F17C 13/001

(57) ABSTRACT

Techniques regarding shielding one or more superconducting devices are provided. For example, one or more embodiments described herein can comprise an apparatus, which can comprise a multi-layer enclosure that shields a superconducting device from a magnetic field and radiation. Further, the multi-layer enclosure can comprise a superconducting material layer that can have a thickness that inhibits a penetration of the multi-layer enclosure by the magnetic field. The multi-layer enclosure can also comprise a metal layer adjacent to the superconducting material layer. The metal layer can have a high thermal conductivity that achieves thermalization with the superconducting material layer. Moreover, the multi-layer enclosure can comprise a radiation shield layer adjacent to the superconducting material layer.

### BACKGROUND

The subject disclosure relates to magnetic field and radiation shielding for one or more superconductive devices, and more specifically, to qubit packaging assemblies and/or multi-layer enclosures that can shield one or more superconducting devices from magnetic fields and/or radiation.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, apparatuses and/or methods that can shield superconducting devices from magnetic fields and/or radiation are described.

According to an embodiment, an apparatus is provided. The apparatus can comprise a multi-layer enclosure that can shield a superconducting device from a magnetic field and radiation. The multi-layer enclosure can comprise a superconducting material layer that can have a thickness that inhibits a penetration of the multi-layer enclosure by the magnetic field. The multi-layer enclosure can further comprise a metal layer adjacent to the superconducting material layer. The metal layer can have a high thermal conductivity that achieves thermalization with the superconducting material layer. The multi-layer enclosure can also comprise a radiation shield layer adjacent to the superconducting material.

According to an embodiment, an apparatus is provided. The apparatus can comprise a qubit packaging assembly having a circuit board positioned between a first metal cover and a second metal cover. The circuit board can house a quantum processor, and a surface of the second metal cover facing the circuit board can comprise a groove that houses an indium seal.

According to an embodiment, a method is provided. The method can comprise electroplating a metal enclosure with a superconducting material to form a magnetic field shield. The method can also comprise depositing a radiation shield onto the superconducting material. The metal enclosure, superconducting material, and radiation shield can form a multi-layer enclosure that shields a superconducting device from a magnetic field and radiation.

### BRIEF DESCRIPTION OF THE DRAWINGS

FIG. 1 illustrates a diagram of an example, non-limiting multi-layer enclosure that can shield one or more superconducting devices from magnetic fields and/or radiation in accordance with one or more embodiments described herein.

FIG. 2 illustrates a diagram of an example, non-limiting multi-layer enclosure that can insulate one or more superconducting devices while also shielding the devices from magnetic fields and/or radiation in accordance with one or more embodiments described herein.

FIG. 3 illustrates a diagram of an example, non-limiting multi-layer enclosure that can insulate one or more superconducting devices while also shielding the devices from magnetic fields and/or radiation in accordance with one or more embodiments described herein.

FIG. 4 illustrates a diagram of an example, non-limiting qubit packaging assembly that can facilitate shielding one or more superconducting qubit processors from detrimental environmental conditions in accordance with one or more embodiments described herein.

FIG. 5 illustrates a diagram of an example, non-limiting qubit packaging assembly housed within a multi-layer enclosure to shield one or more superconducting processors from magnetic fields and/or radiation in accordance with one or more embodiments described herein.

FIG. 6 illustrates a diagram of an example, non-limiting multi-layer enclosure that can shield one or more superconducting devices from magnetic fields and/or radiation during a first stage of manufacturing in accordance with one or more embodiments described herein.

FIG. 7 illustrates a diagram of an example, non-limiting multi-layer enclosure that can shield one or more superconducting devices from magnetic fields and/or radiation during a second stage of manufacturing in accordance with one or more embodiments described herein.

FIG. 8 illustrates a diagram of an example, non-limiting multi-layer enclosure that can shield one or more superconducting devices from magnetic fields and/or radiation during a third stage of manufacturing in accordance with one or more embodiments described herein.

FIG. 9 illustrates a diagram of an example, non-limiting multi-layer enclosure that can shield one or more superconducting devices from magnetic fields and/or radiation during a fourth stage of manufacturing in accordance with one or more embodiments described herein.

FIG. 10 illustrates a flow diagram of an example, non-limiting method that can facilitate manufacturing one or more multi-layer enclosures that can shield one or more superconducting devices from magnetic fields and/or radiation in accordance with one or more embodiments described herein.

FIG. 11 illustrates a flow diagram of an example, non-limiting method that can facilitate manufacturing one or more multi-layer enclosures that can shield one or more superconducting devices from magnetic fields and/or radiation in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details. Additionally, features depicted in the drawings with like shading, cross-hatching, and/or coloring can comprise shared compositions and/or materials.

Radiation can decrease the performance of various superconducting devices, such as superconducting qubits and/or microwave resonators. For example, radiation can impair the tunability, fixed frequency of superconducting qubits, and/or qubit lifetime. Possible sources of radiation can include, for example: stray light, cosmic rays, background radioactivity, slow heat release of various defect, and/or thermal radiation. Radiation can generate thermal quasiparticles, thereby reducing cavity resonator quality factor and impacting the coherence of the superconducting qubits as well as reducing qubit fidelities. Additionally, magnetic fields are known to reduce the performance of both qubits and various types of resonators. For instance, superconducting circuits are cooled in a very low magnetic field in order to minimize the number of trapped vortices.

Various embodiments described herein can regard apparatuses and/or methods for shielding one or more superconducting devices from magnetic fields and/or multiple sources of stray radiation. One or more embodiments, for example, can regard one or more multi-layer enclosures that can shield against magnetic fields and/or radiation while facilitating various thermal conditions (e.g., facilitating rapid cooling of the enclosure and/or the one or more superconducting devices). Additionally, one or more embodiments can include one or more qubit assembly packages that can facilitate shielding one or more superconducting quit processors. Further, various embodiments described herein can comprise one or more manufacturing methods regarding the multi-layer enclosures and/or qubit packaging assemblies.

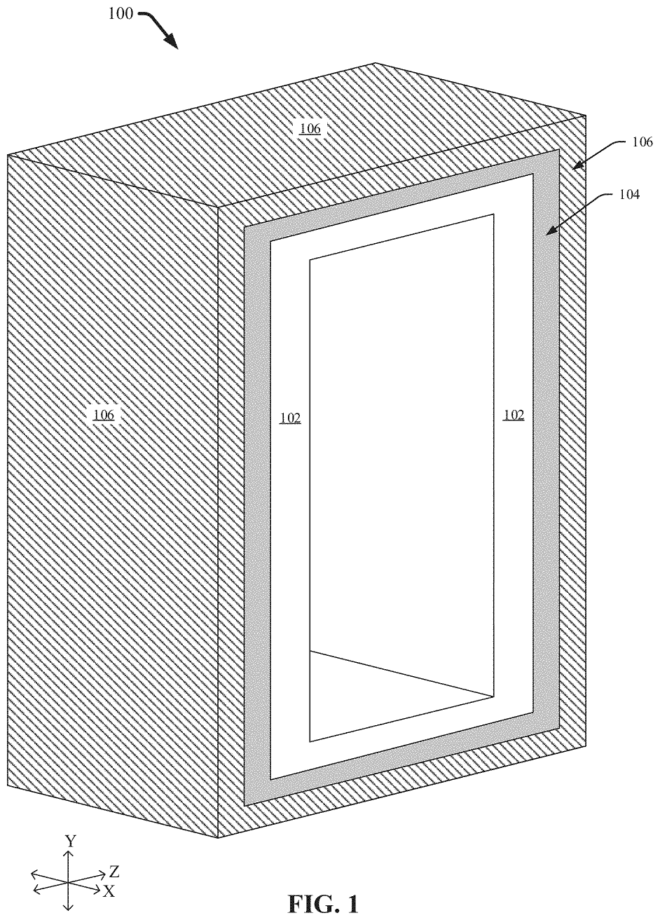

FIG. 1 illustrates a diagram of an example, non-limiting multi-layer enclosure 100 that can shield one or more superconducting devices from magnetic fields and/or radiation in accordance with one or more embodiments described herein. Repetitive description of like elements employed in other embodiments described herein is omitted for sake of brevity. In various embodiments, the multi-layer enclosure 100 can comprise one or more metal layers 102, superconducting material layers 104, and/or radiation shield layer 106. FIG. 1 depicts a cross-sectional view of the multi-layer enclosure 100 so as to illustrate the structure of the various layers.

In one or more embodiments, the one or more metal layers 102 can be free of magnetic impurities. For example, the one or more metal layers 102 can be annealed in various gases (e.g., low pressure oxygen gas or a vacuum) to eliminate impurities and/or oxygen vacancies. Further, the one or more metal layers 102 can have a high thermal conductivity so as to facilitate thermalization between the various layers of the multi-layer enclosure 100 (e.g., achieving thermalization with the one or more superconducting material layers 104). Example materials that can be comprised within the one or more metal layers 102 can include, but are not limited to: oxygen-free high thermal conductivity (“OFHC”) copper, electrolytic tough pitch (“ETP”) copper, gold, silver, a combination thereof, and/or the like. One of ordinary skill in the art will recognize that a thickness of the one or more metal layers 102 can vary depending on the size and/or function of the multi-layer enclosure 100. For instance, an exemplary thickness range for the one or more metal layers 102 can be greater than or equal to 2 millimeters (mm) and less than or equal to 1 centimeter (cm). Further, the thickness of the one or more metal layers 102 can be uniform throughout the multi-layer enclosure 100 (e.g., as shown in FIG. 1) or can vary within the multi-layer enclosure 100.

In one or more embodiments, the one or more superconducting material layers 104 can comprise one or more materials that can exhibit superconducting properties, such as little to no electrical resistance and/or expulsion of magnetic flux. Example materials that can comprise the one or more superconducting material layers 104 can include, but are not limited to: indium, rhenium, yttrium barium copper oxide, tin (Sn), aluminum (Al), titanium nitride (TiN), a combination thereof, and/or the like. In various embodiments, the one or more superconducting material layers 104 can have a thickness higher than the penetration depth of one or more magnetic fields. One of ordinary skill in the art will recognize that a thickness of the one or more superconducting material layers 104 can vary depending on the size and/or function of the multi-layer enclosure 100. For instance, an exemplary thickness range for the one or more superconducting material layers 104 can be greater than or equal to 200 microns and less than or equal to 1 mm. Further, the thickness of the one or more superconducting material layers 104 can be uniform throughout the multi-layer enclosure 100 (e.g., as shown in FIG. 1) or can vary within the multi-layer enclosure 100.

In one or more embodiments, the one or more radiation shield layers 106 can comprise materials that can reflect and/or refract ionizing radiation and/or infrared (“IR”) radiation. Example materials that can comprise the one or more radiation shield layers 106 can include, but are not limited to: AEROGLAZE® Z306 coating, and/or the like. One of ordinary skill in the art will recognize that a thickness of the one or more radiation shield layers 106 can vary depending on the size and/or function of the multi-layer enclosure 100. For instance, an exemplary thickness range for the one or more radiation shield layers 106 can be 1 mm or thicker. Further, the thickness of the one or more radiation shield layers 106 can be uniform throughout the multi-layer enclosure 100 (e.g., as shown in FIG. 1) or can vary within the multi-layer enclosure 100.

As shown in FIG. 1, the one or more superconducting material layers 104 can be adjacent to the one or more metal layers 102, whereupon the one or more radiation shield layers 106 can be further adjacent the one or more superconducting material layers 104. In various embodiments, the one or more superconducting material layers 104 can be deposited onto the one or more metal layers 102 via electroplating, sputtering, thermal evaporation, physical vapor disposition (“PVD”), a combination thereof, and/or the like. In various embodiments, the multi-layer enclosure 100 can house one or more superconducting devices (e.g., quantum processors, qubits, microwave resonators, a combination thereof, and/or the like). For example, the one or more superconducting devices can be positioned within a cavity comprised within the multi-layer enclosure 100 (e.g., as defined by the one or more metal layers 102 in FIG. 1). Thereby, the multi-layer enclosure 100 can substantially surround the one or more superconducting devices and/or shield the one or more superconducting devices from magnetic fields and/or radiation.

For example, the one or more superconducting material layers 104 can serve as a magnetic field shield by inhibiting one or more magnetic fields from penetrating the multi-layer enclosure 100 and interacting with the one or more superconducting devices. Also, the one or more radiation shield layers 106 can serve as a radiation shield by inhibiting radiation (e.g., IR radiation) from penetrating the multi-layer enclosure 100 and interacting with the one or more superconducting devices. Further, the one or more metal layers 102 can provide high thermal conductivity to the multi-layer enclosure 100 to facilitate rapid thermal changes in the condition of the multi-layer enclosure 100. For example, the one or more metal layers 102 can comprise OFHC copper that can facilitate in cooling the multi-layer enclosure 100 to temperatures conducive to operation of the one or more superconducting devices.

In various embodiments, the multi-layer enclosure 100 can further comprise one or more doors to facilitate access to the inside cavity of the multi-layer enclosure 100. For example, the one or more doors can comprise the same multi-layer structure as the body of the multi-layer enclosure 100 (e.g., as depicted in FIG. 1). In some embodiments, the multi-layer enclosure 100 can comprise two or more portions that can be combined together to complete the multi-layer enclosure 100. By combining the portions around the one or more superconducting devices, the completed multi-layer enclosure 100 can substantially surround the one or more superconducting devices. For example, each portion of the multi-layer enclosure 100 can comprise the same multi-layer structure as the body of the multi-layer enclosure 100 (e.g., as depicted in FIG. 1). For instance, FIG. 1 can depict the cross-section of a multi-layer enclosure 100 formed from the combination of two or more portions.

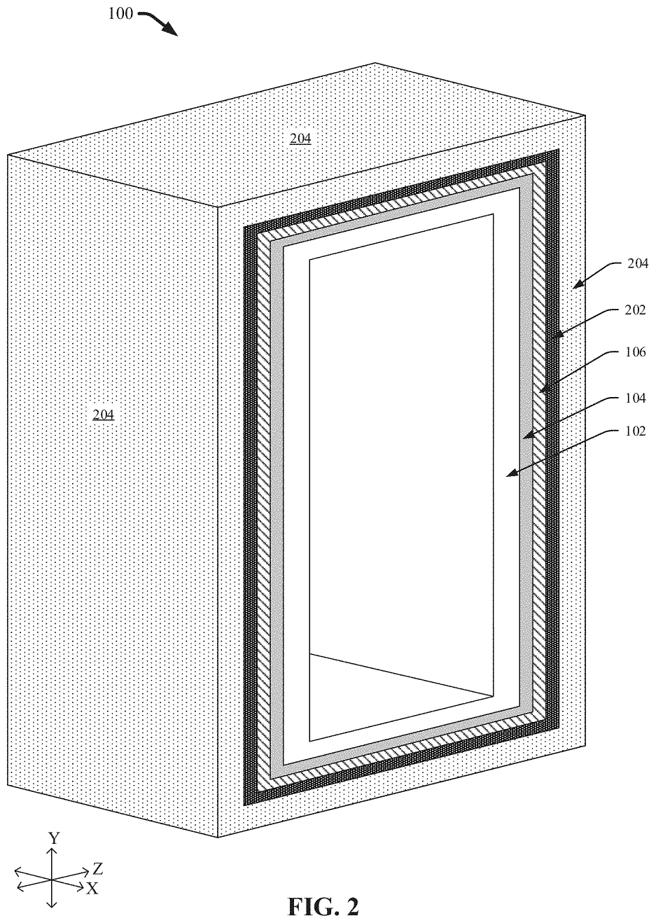

FIG. 2 illustrates a diagram of the example, non-limiting multi-layer enclosure 100 further comprising one or more cryogenic magnetic shielding layers 202 and/or superinsulation layers 204. Repetitive description of like elements employed in other embodiments described herein is omitted for sake of brevity. As shown in FIG. 2, in one or more embodiments the one or more cryogenic magnetic shielding layers 202 can be adjacent to the one or more radiation layers 106, and/or the one or more superinsulation layers 204 can be adjacent to the one or more cryogenic magnetic shielding layers 202.

In one or more embodiments, the one or more cryogenic magnetic shielding layers 202 can comprise one or more materials that can be highly permeable and/or provide electromagnetic interference (“EMI”) shielding in near absolute zero environment. Example materials that can comprise the cryogenic magnetic shielding layers 202 can include, but are not limited to, murinite, and/or the like. For instance, the cryogenic magnetic shielding layers 202 can comprise cryoperm. One of ordinary skill in the art will recognize that a thickness of the one or more cryogenic magnetic shielding layers 202 can vary depending on the size and/or function of the multi-layer enclosure 100. For instance, an exemplary thickness range for the one or more one or more cryogenic magnetic shielding layers 202 can be greater than or equal to 100 microns and less than or equal to 1 mm. Further, the thickness of the one or more cryogenic magnetic shielding layers 202 can be uniform throughout the multi-layer enclosure 100 (e.g., as shown in FIG. 1) or can vary within the multi-layer enclosure 100.

In various examples, the one or more cryogenic magnetic shielding layers 202 can be wrapped light-tight around the one or more radiation shield layers 106. Additionally, multiple sheets of the one or more cryogenic magnetic shielding layers 202 can be welded together to achieve a desired thickness. The one or more cryogenic magnetic shielding layers 202 can further increase the multi-layer enclosure's 100 capacity to shield against magnetic fields. For instance, the one or more cryogenic magnetic shielding layers 202 can provide magnetic field shielding from room temperature environments.

In one or more embodiments, the one or more superinsulation layers 204 comprise one or more superinsulators (e.g., one or more materials that can exhibit near-infinite electrical resistance). Example materials that can comprise the one or more superinsulation layers 204 can include, but are not limited to: aluminized mylar film (e.g., having an exemplary thickness of 125 microns), aluminum foil (e.g., high purity foil with low emissivity qualities that enable superinsulation below 77 degrees Kalvin and/or having an exemplary nominal thickness of 0.08 mm), a superinsulated film with a vacuum deposited aluminum layer deposited on one or two sides of the film to approximately 400 angstrom to provide an effective radiation barrier, a combination thereof, and/or the like. One of ordinary skill in the art will recognize that a thickness of the one or more superinsulation layers 204 can vary depending on the size and/or function of the multi-layer enclosure 100. Further, the thickness of the one or more superinsulation layers 204 can be uniform throughout the multi-layer enclosure 100 (e.g., as shown in FIG. 1) or can vary within the multi-layer enclosure 100. In various embodiments, the one or more superinsulation layers 204 can provide a crinkled surface with high mechanical strength and/or tear resistance (e.g., rendering the one or more superinsulation layers 204 ideal for cryogenic fabrication insulation).

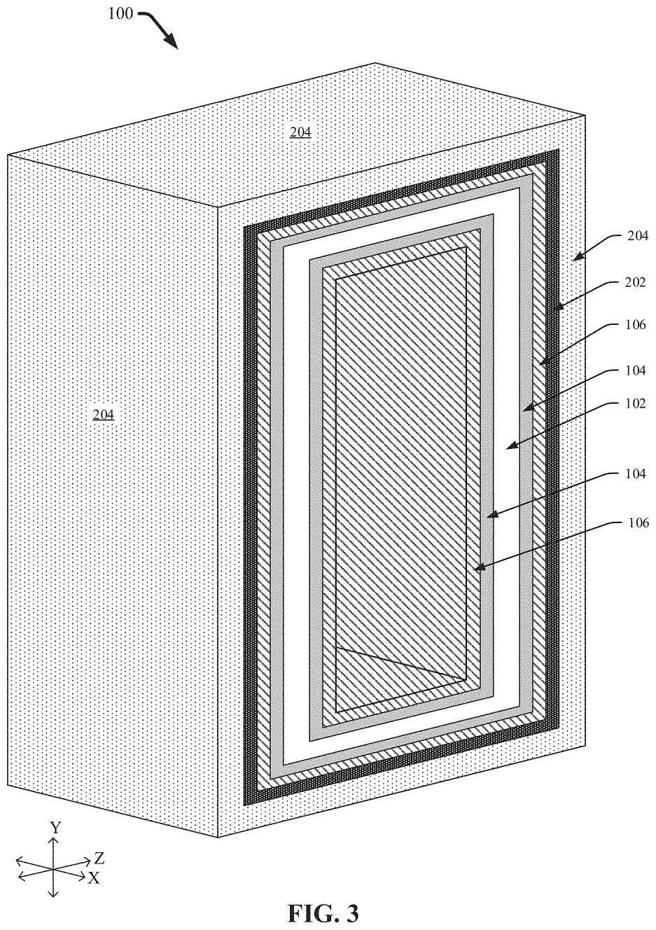

FIG. 3 illustrates a diagram of the example, non-limiting multi-layer enclosure 100 further comprising multiple layers of the superconducting material layers 104 and/or radiation shield layers 106. Repetitive description of like elements employed in other embodiments described herein is omitted for sake of brevity. As shown in FIG. 3, the multi-layer enclosure 100 can comprise multiples of the various layers described herein. For instance, FIG. 3 illustrates an embodiment of the multi-layer enclosure 100 comprise two superconducting material layers 104 and/or radiation shield layers 106.

For example, in one or more embodiments an outer surface and an inner surface of a metal layer 102 can be electroplated with superconducting material layers 104; thereby forming a structure in which the metal layer 102 is positioned between two superconducting material layers 104. Further, a radiation shield layer 106 can be positioned adjacent to each of the superconducting material layers 104 such that the metal layer 102 and two superconducting material layers 104 can be located between two radiation shield layers 106 (e.g., as shown in FIG. 3) Likewise, in various embodiments the multi-layer enclosure 100 can comprise multiples of the metal layer 102, cryogenic magnetic shielding layer 202, and/or superinsulation layer 204. Further, although FIG. 3 depicts two superconducting material layers 104 and two radiation shield layers 106, the architecture of the multi-layer enclosure 100 is not so limited. For example, embodiments of the multi-layer enclosure 100 comprising three or more layers of the metal layer 102, superconducting material layer 104, radiation shielding layer 106, cryogenic magnetic shielding layer 202, and/or superinsulation layer 204 are also envisaged.

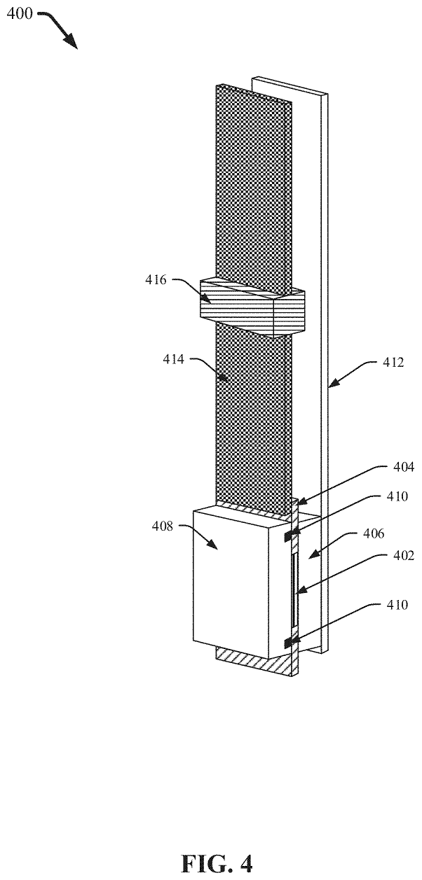

FIG. 4 illustrates a diagram of an example, non-limiting qubit packaging assembly 400 that can facilitate shielding one or more quantum processors from magnetic shields in accordance with one or more embodiments described herein. Repetitive description of like elements employed in other embodiments described herein is omitted for sake of brevity. The qubit packaging assembly 400 can comprise one or more silicon chips 402 having one or more quantum processors (e.g., one or more superconducting qubits and/or microwave resonators).

The one or more silicon chips 402 can be positioned on one or more circuit boards 404 (e.g., printed circuit boards). Further, the one or more circuit boards 404 can be positioned between a first metal cover 406 and a second metal cover 408 (e.g., as shown in FIG. 4). In various embodiments, the first metal cover 406 and/or the second metal cover 408 can be annealed in various gases (e.g., low oxygen pressure) to eliminate impurities and/or oxygen vacancies. Further, the first metal cover 406 and/or the second metal cover 408 can have a high thermal conductivity. Example materials that can comprise the first metal cover 406 and/or the second metal cover 408 can include, but are not limited to: OFHC copper, ETP copper, gold, silver, a combination thereof, and/or the like. One of ordinary skill in the art will recognize that a thickness of the first metal cover 406 and/or the second metal cover 408 can vary depending on the size and/or function of the qubit packaging assembly 400. For instance, an exemplary thickness range for the first metal cover 406 and/or the second metal cover 408 can be a few millimeters thick. Further, the thickness of the first metal cover 406 and/or the second metal cover 408 can be uniform or can vary. Additionally, a thickness of the first metal cover 406 can be substantially the same as a thickness of the second metal cover 408. Further, the shape of the first metal cover 406 and/or second metal cover 408 can follow the chip shape and design in order to secure good thermal contact. Alternatively, one or more embodiments of the qubit packaging assembly 400 can comprise the first metal cover 406 having a first thickness and the second metal cover 408 having a second thickness.

In one or more embodiments, the second metal cover 408 can comprise one or more grooves in a surface of the second metal cover 408 that faces the one or more circuit boards 404. Further, one or more indium seals 410 can be positioned within the one or more grooves. The one or more indium seals 410 can enable an interface between the second metal cover 408 and the one or more circuit boards 404 without compromising the structural integrity of the one or more circuit boards 404. In various embodiments, the second metal cover 408 can be braided to thermalize the second metal cover 408 due to indium becoming superconducting at low temperatures. Also, in one or more embodiments, the first metal cover 406 can be coupled to one or more metal mounting bracket 412. In various embodiments, the one or more metal mounting brackets 412 can be annealed in various gases (e.g., low pressure oxygen) to eliminate impurities and/or oxygen vacancies. Further, the metal mounting bracket 412 can have a high thermal conductivity. Example materials that can comprise the one or more metal mounting brackets 412 can include, but are not limited to: OFHC copper, ETP copper, gold, silver, a combination thereof, and/or the like.

Further, in one or more embodiments the one or more circuit boards 404 can be operably coupled to one or more coaxial cables 414 that can establish an electrical connection with the one or more quantum processors. Additionally, one or more impedance-matched low-pass filters 416 can be operably coupled to the one or more coaxial cables 414. For instance, the one or more one or more impedance-matched low-pass filters 416 can be eccosorb filters.

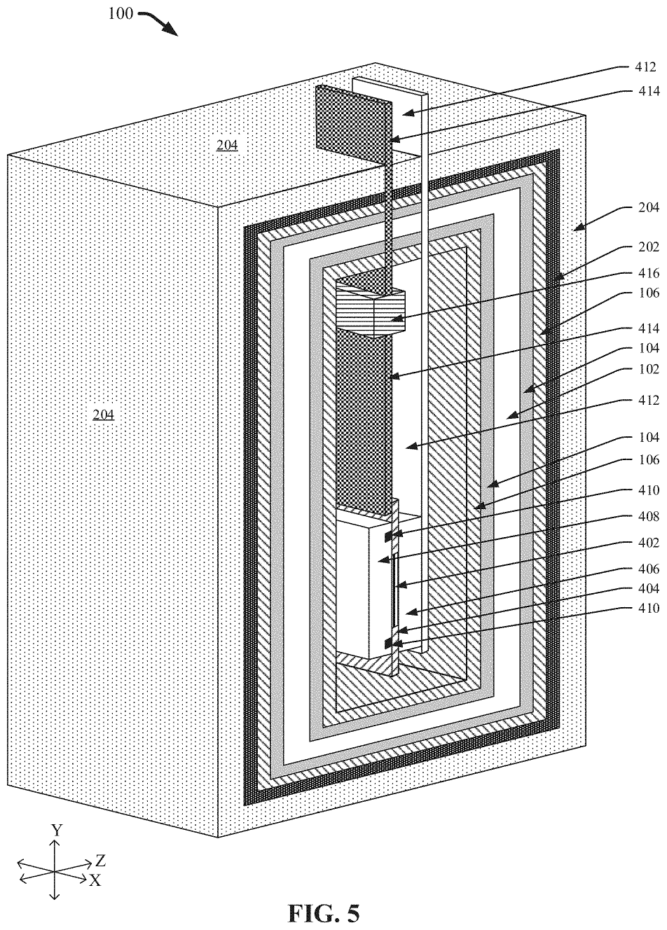

FIG. 5 illustrates a diagram of the example, non-limiting multi-layer enclosure 100 shielding one or more of the qubit packaging assemblies 400 in accordance with one or more embodiments described herein. Repetitive description of like elements employed in other embodiments described herein is omitted for sake of brevity. In various embodiments, the one or more superconducting devices shielded by the one or more multi-layer enclosures 100 can be the one or more qubit packaging assemblies 400 described herein.

In various embodiments, the one or more impedance-matched low-pass filters 416, first metal cover 406, second metal cover 408, one or more silicon chips 402, one or more circuit boards 404, and/or indium seals 410 can be substantially surrounded by the one or more multi-layer enclosures 100. As shown in FIG. 5, the one or more coaxial cables 414 and/or metal mounting brackets 412 can extend through the one or more multi-layer enclosures 100. For example, the one or more coaxial cables 414 can extend through the one or more multi-layer enclosure 100 so as to electrically connect the one or more qubit packaging assemblies 400 positioned within the multi-layer enclosure 100 to one or more devices positioned outside the multi-layer enclosure 100. While FIG. 5 depicts a single qubit packaging assembly 400 housed within the multi-layer enclosure 100, the architecture of the multi-layer enclosure 100 is not so limited. For example, multi-layer enclosures 100 that can house multiple superconducting devices (e.g., multiple qubit packaging assemblies 400) are also envisaged. For example, the dimensions of the one or more multi-layer enclosures 100 (e.g., along the “Y”, “X”, and/or “Z” axes) can vary depending on the dimension and/or number of superconducting devices being shielded by the one or more multi-layer enclosures 100. Additionally, while FIGS. 1-3 and 5 depict multi-layer enclosures 100 having a rectangular shape, the architecture of the one or more multi-layer enclosures 100 is not so limited. For example, the one or more multi-layer enclosures 100 can have one or more other shapes such as a cylindrical shape.

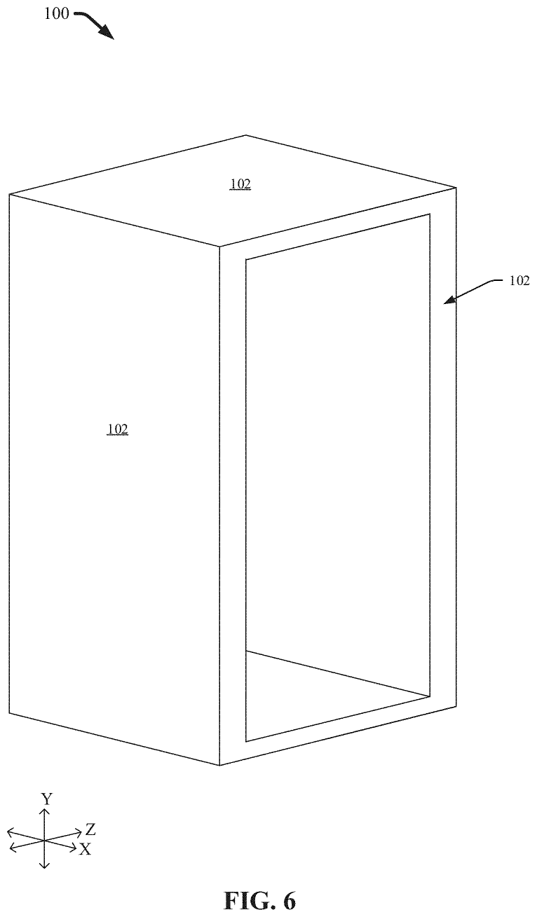

FIG. 6 illustrates a diagram of the example, non-limiting multi-layer enclosure 100 during a first stage of manufacturing in accordance with one or more embodiments described herein. Repetitive description of like elements employed in other embodiments described herein is omitted for sake of brevity. FIG. 6 illustrates a cross-sectional view of an embodiment of the multi-layer enclosure 100 during a first stage of manufacturing.

As shown in FIG. 6, during the first stage of manufacturing the one or more metal layers 102 are provided. In one or more embodiments, the one or more metal layers 102 can define the inner cavity of the multi-layer enclosure 100. Thus, the one or more metal layers 102 can be shaped to dimensions based on the one or more superconducting devices intended to be shielded by the multi-layer enclosure 100. In various embodiments, the one or more metal layers 102 can comprise OFHC copper. Additionally, the one or more metal layers 102 can be electropolished to facilitate coating by one or more other layers.

For example, the one or more metal layers 102 can be cleaned (e.g., using acetone and/or isopropyl alcohol) to remove any debris and/or grease residue left from forming the shape of the metal layers 102. Additionally, one or more surfaces of the metal layers 102 can be etched to remove any oxide layers. Following the etching, the one or more surfaces of the metal layers 102 can be electropolished (e.g., using one or more commercially available solutions) to smooth the surfaces.

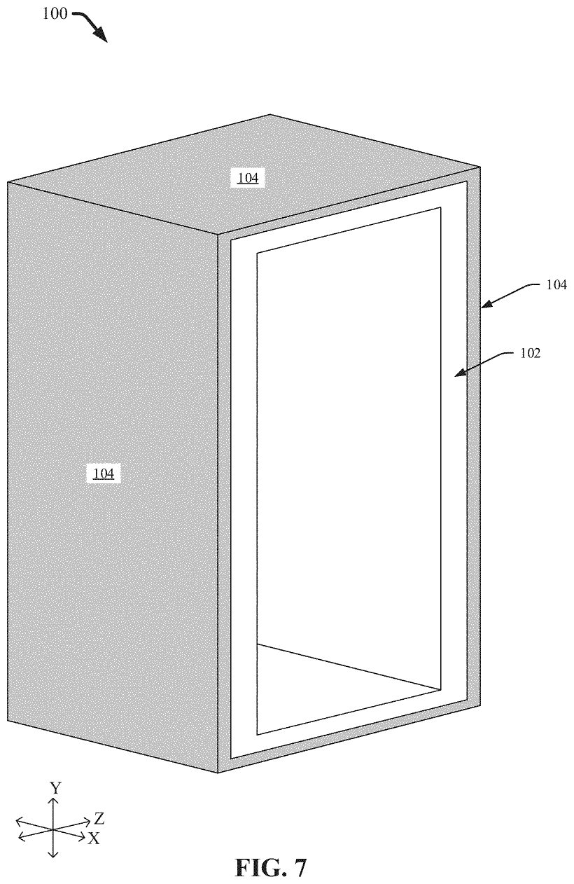

FIG. 7 illustrates a diagram of the example, non-limiting multi-layer enclosure 100 during a second stage of manufacturing in accordance with one or more embodiments described herein. Repetitive description of like elements employed in other embodiments described herein is omitted for sake of brevity. FIG. 7 illustrates a cross-sectional view of an embodiment of the multi-layer enclosure 100 during a second stage of manufacturing.

As shown in FIG. 7, during the second stage of manufacturing the one or more superconducting material layers 104 can be deposited onto the one or more metal layers 102. For example, the one or more superconducting material layers 104 can be electroplated onto the electropolished surfaces of the one or more metal layers 102. Thereby, the one or more metal layers 102 can be coated with a film of the one or more superconducting material layers 104. The one or more electroplating processes can be performed using one or more commercially available solutions. Further, in one or more embodiments the one or more electroplating processes can deposit a uniform, or substantially uniform, film of the one or more superconducting material layers 104 onto the one or more surfaces of the metal layer 102.

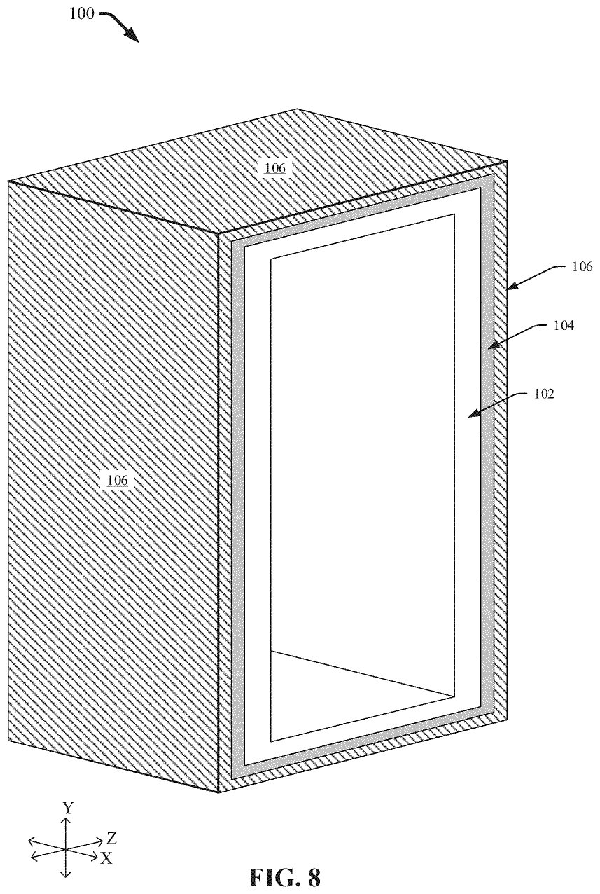

FIG. 8 illustrates a diagram of the example, non-limiting multi-layer enclosure 100 during a third stage of manufacturing in accordance with one or more embodiments described herein. Repetitive description of like elements employed in other embodiments described herein is omitted for sake of brevity. FIG. 8 illustrates a cross-sectional view of an embodiment of the multi-layer enclosure 100 during a third stage of manufacturing.

As shown in FIG. 8, during the third stage of manufacturing the one or more radiation shield layers 106 can be deposited onto the one or more superconducting material layers 104. For instance, in one or more embodiments the one or more radiation shield layers 106 can be painted onto the one or more superconducting material layers 104. Further, the one or more radiation shield layers 106 can provide protection against, for example: IR radiation, ionizing radiation, high-frequency electromagnetic fields, low-frequency electric fields, radio frequency radiation, microwave radiation, a combination thereof, and/or the like. In various embodiments, a uniform, or substantially uniform, distribution of the one or more radiation shield layers 106 can be deposited onto the one or more superconducting material layers 104. In some embodiments, distribution of the one or more radiation shield layers 106 onto the one or more superconducting material layers 104 can be non-uniform.

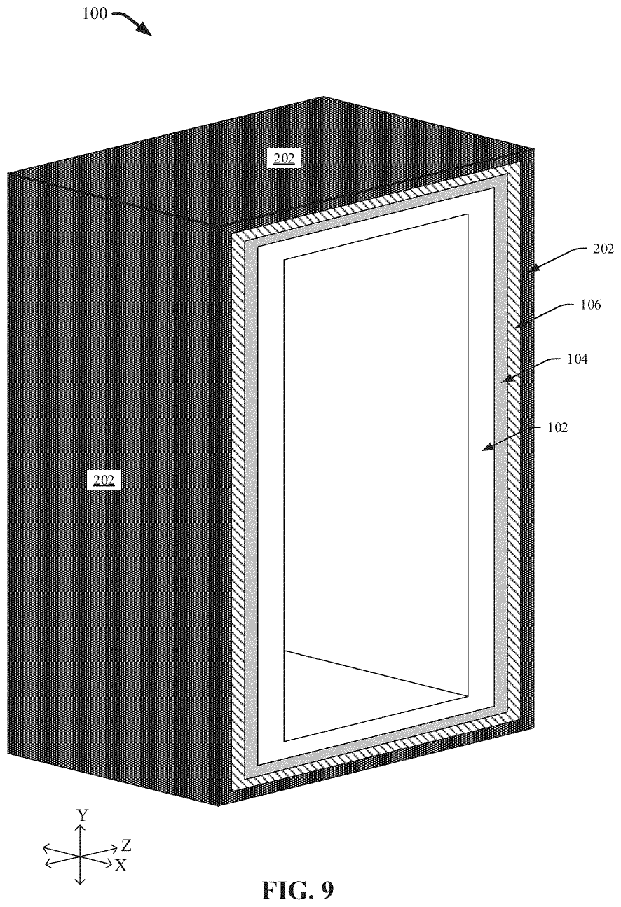

FIG. 9 illustrates a diagram of the example, non-limiting multi-layer enclosure 100 during a fourth stage of manufacturing in accordance with one or more embodiments described herein. Repetitive description of like elements employed in other embodiments described herein is omitted for sake of brevity. FIG. 9 illustrates a cross-sectional view of an embodiment of the multi-layer enclosure 100 during a fourth stage of manufacturing.

As show in FIG. 9, during the fourth stage of manufacturing the one or more cryogenic magnetic shielding layers 202 can be deposited onto the one or more radiation shielding layers 106. In various embodiments, the one or more cryogenic magnetic shielding layers 202 can be wrapped light-tight around the one or more radiation shielding layers 106. For example, multiple sheets of the one or more cryogenic magnetic shielding layers 202 can be welded together to form a light-tight layer around the one or more radiation shielding layers 106. Furthermore, during a fifth stage of manufacturing the one or more superinsulation layers 204 can be deposited onto the one or more cryogenic magnetic shielding layers 202 to achieve the structure depicted in FIG. 2.

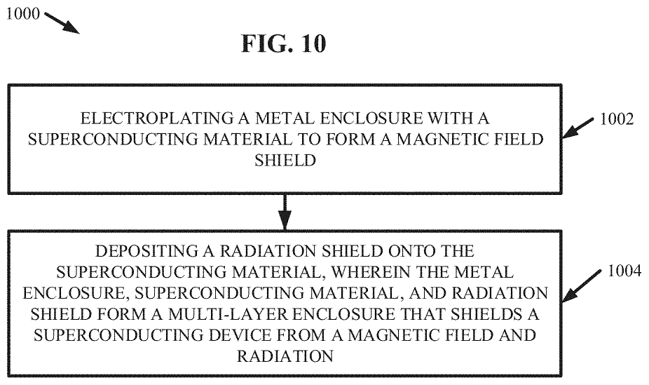

FIG. 10 illustrates a flow diagram of an example, non-limiting method 1000 that can facilitate manufacturing one or more multi-layer enclosures 100 that can shield one or more superconducting devices from magnetic fields and/or radiation in accordance with one or more embodiments described herein. Repetitive description of like elements employed in other embodiments described herein is omitted for sake of brevity.

At 1002, the method 1000 can comprise electroplating a metal enclosure (e.g., one or more metal layers 102) with a superconducting material (e.g., one or more superconducting material layers 104) to form a magnetic field shield. For example, the electroplating at 1002 can be performed in accordance with the first and/or second stages of manufacturing described herein. For instance, oxide layers on the metal enclosure can be removed via one or more etching processes. Further, one or more surfaces of the metal enclosure can be electropolished so as to smooth the surfaces in preparation of depositing the superconducting material. In various embodiments, the electroplating can coat a film of the superconducting material (e.g., the one or more superconducting material layers 104) onto the metal enclosure (e.g., one or more metal layers 102), as described herein.

At 1004, the method 1000 can comprise depositing a radiation shield (e.g., one or more radiation shield layers 106) onto the superconducting material (e.g., superconducting material layers 104), wherein the metal enclosure (e.g. metal layers 102), superconducting material (e.g., superconducting material layers 104), and radiation shield (e.g., radiation shield layers 106) can form a multi-layer enclosure 100 that can shield one or more superconducting devices from a magnetic field and/or radiation. For instance, in one or more embodiments the radiation shield can be painted onto the superconducting material. The multi-layer enclosure 100 formed at 1004 can exhibit magnetic field and/or radiation shielding while also exhibiting thermal conductivity properties conducive to operation of the one or more superconducting devices. For example, the metal enclosure (e.g., one or more metal layers 102) can enable the multi-layer enclosure 100 to cool rapidly to meet the temperature conditions that are optimal for operating the one or more superconducting devices.

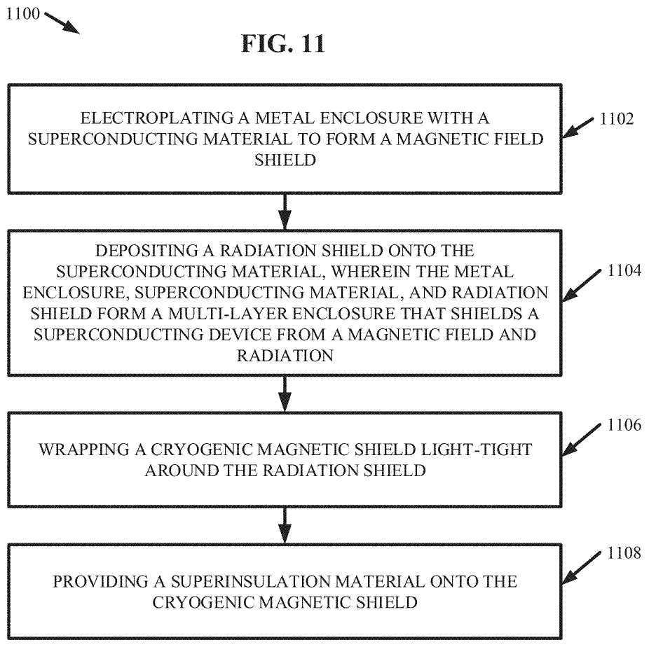

FIG. 11 illustrates a flow diagram of an example, non-limiting method 1100 that can facilitate manufacturing one or more multi-layer enclosures 100 that can shield one or more superconducting devices from magnetic fields and/or radiation in accordance with one or more embodiments described herein. Repetitive description of like elements employed in other embodiments described herein is omitted for sake of brevity.

At 1102, the method 1100 can comprise electroplating a metal enclosure (e.g., one or more metal layers 102) with a superconducting material (e.g., one or more superconducting material layers 104) to form a magnetic field shield. For example, the electroplating at 1102 can be performed in accordance with the first and/or second stages of manufacturing described herein. For instance, oxide layers on the metal enclosure can be removed via one or more etching processes. Further, one or more surfaces of the metal enclosure can be electropolished so as to smooth the surfaces in preparation of depositing the superconducting material. In various embodiments, the electroplating can coat a film of the superconducting material (e.g., the one or more superconducting material layers 104) onto the metal enclosure (e.g., one or more metal layers 102), as described herein.

At 1104, the method 1100 can comprise depositing a radiation shield (e.g., one or more radiation shield layers 106) onto the superconducting material (e.g., superconducting material layers 104), wherein the metal enclosure (e.g. metal layers 102), superconducting material (e.g., superconducting material layers 104), and radiation shield (e.g., radiation shield layers 106) can form a multi-layer enclosure 100 that can shield one or more superconducting devices from a magnetic field and/or radiation. For instance, in one or more embodiments the radiation shield can be painted and/or sprayed onto the superconducting material. The multi-layer enclosure 100 formed at 1104 can exhibit magnetic field and/or radiation shielding while also exhibiting thermal conductivity properties conducive to operation of the one or more superconducting devices. For example, the metal enclosure (e.g., one or more metal layers 102) can enable the multi-layer enclosure 100 to cool rapidly to meet the temperature conditions that are optimal for operating the one or more superconducting devices.

At 1106, the method 1100 can comprise providing a cryogenic magnetic shield (e.g., cryogenic magnetic shielding layers 202) onto the radiation shield (e.g., radiation shielding layers 106). For example, the depositing at 1106 can be performed in accordance with the fourth stage of manufacturing described herein. For instance, one or more sheets of the cryogenic magnetic shield can be welded together and wrapped light-tight around the radiation shield (e.g., radiation shield layers 106).

At 1108, the method 1100 can comprise providing a superinsulation material (e.g., one or more superinsulation layers 204) onto the cryogenic magnetic shield (e.g., one or more cryogenic magnetic shielding layers 202). The superinsulation material can comprise at least one member selected from a group consisting of: aluminized mylar film (e.g., having an exemplary thickness of 125 microns), aluminum foil (e.g., high purity foil with low emissivity qualities that enable superinsulation below 77 degrees Kalvin and/or having an exemplary nominal thickness of 0.08 mm), a superinsulated film with a vacuum deposited aluminum layer deposited on one or two sides of the film to approximately 400 angstrom to provide an effective radiation barrier. For example, the depositing at 1108 can be performed in accordance with the fifth stage of manufacturing described herein. The cryogenic magnetic shield and/or superinsulation material deposited at 1106 and/or 1108 can widen the temperature range at which the multi-layer enclosure 100 can provide shielding against magnetic fields and/or radiation.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

It is, of course, not possible to describe every conceivable combination of components, products and/or methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An apparatus, comprising:
a multi-layer enclosure that shields a superconducting device from a magnetic field and radiation, wherein the multi-layer enclosure comprises:
a superconducting material layer having a thickness that inhibits a penetration of the multi-layer enclosure by the magnetic field;
a metal layer adjacent to the superconducting material layer, the metal layer having a high thermal conductivity that achieves thermalization with the superconducting material layer; and
a radiation shield layer adjacent to the superconducting material layer.

2. The apparatus of claim 1, wherein the multi-layer enclosure further comprises:
a cryogenic magnetic shielding layer adjacent to the radiation shield layer, wherein the cryogenic magnetic shielding layer is wrapped light-tight around the radiation shield layer; and
a superinsulation layer adjacent to the cryogenic magnetic shielding layer.

3. The apparatus of claim 2, wherein the superconducting material layer is deposited onto the metal layer, wherein the radiation shield layer is deposited onto the superconducting material layer, wherein the cryogenic magnetic shielding layer is deposited onto the radiation shield layer, and wherein the superinsulation layer is deposited onto the cryogenic magnetic shielding layer.

4. The apparatus of claim 1, wherein the multi-layer enclosure further comprises:
a second superconducting material layer, wherein the metal layer is positioned between the superconducting material layer and the second superconducting material layer; and
a second radiation shield layer positioned adjacent to the second superconducting material layer.

5. The apparatus of claim 1, wherein the superconducting material layer is deposited onto the metal layer, and wherein the radiation shield layer is deposited onto the superconducting material layer.

6. The apparatus of claim 1, wherein the metal layer comprises at least one member selected from a group consisting of oxygen free high thermal conductivity copper, electrolytic tough pitch copper, gold, and silver.

7. The apparatus of claim 1, wherein the superconducting device comprises a qubit packaging assembly, and wherein the multi-layer enclosure substantially surrounds the qubit packaging assembly.

8. The apparatus of claim 7, wherein the qubit packaging assembly comprises:
a circuit board positioned between a first metal cover and a second metal cover, wherein the circuit board houses a quantum processor, and wherein the qubit packaging assembly is mounted within the multi-layer enclosure via a coupling between a metal mounting bracket and the first metal cover.

9. The apparatus of claim 8, wherein a surface of the second metal cover facing the circuit board comprises a groove that houses an indium seal.

10. The apparatus of claim 9, further comprising:
a coaxial cable extending through the multi-layer enclosure and operably coupled to the circuit board; and
an impedance matched low-pass filter positioned within the multi-layer enclosure and operably coupled to the coaxial cable.

11. An apparatus, comprising:
a qubit packaging assembly having a circuit board positioned between a first metal cover and a second metal cover, wherein the circuit board houses a quantum processor, and wherein a surface of the second metal cover facing the circuit board comprises a groove that houses an indium seal.

12. The apparatus of claim 11, wherein the first metal cover is coupled to a metal mounting bracket that supports the qubit packaging assembly.

13. The apparatus of claim 12, further comprising:
a coaxial cable that is operably coupled to the circuit board; and
an impedance-matched low-pass filter operably coupled to the coaxial cable.

14. The apparatus of claim 13, further comprising:
a multi-layer enclosure that shields the qubit packaging assembly from a magnetic field and radiation, wherein the qubit packaging assembly and the impedance-matched low-pass filter are substantially surrounded by the multi-layer enclosure, and wherein the metal mounting bracket and the coaxial cable travel through the multi-layer enclosure.

15. The apparatus of claim 14, wherein the multi-layer enclosure comprises:
a superconducting material layer having a thickness greater than a penetration depth of the magnetic field;
a metal layer adjacent to the superconducting material layer, the metal layer having a high thermal conductivity that achieves thermalization with the superconducting material layer; and
a radiation shield layer positioned adjacent to the superconducting material layer.

16. The apparatus of claim 15, wherein the superconducting material layer is deposited onto the metal layer, and wherein the radiation shield layer is deposited onto the superconducting material layer.

17. A method, comprising:
electroplating a metal enclosure with a superconducting material to form a magnetic field shield; and
depositing a radiation shield onto the superconducting material, wherein the metal enclosure, superconducting material, and radiation shield form a multi-layer enclosure that shields a superconducting device from a magnetic field and radiation.

18. The method of claim 17, further comprising:
wrapping a cryogenic magnetic shield light-tight around the radiation shield; and
providing a superinsulation material onto the cryogenic magnetic shield.

19. The method of claim 17, wherein the superconducting device comprises a qubit packaging assembly that comprises a circuit board positioned between a first metal cover and a second metal cover, wherein the circuit board houses a quantum processor, wherein the qubit packaging assembly is mounted within the multi-layer enclosure via a coupling between a metal mounting bracket and the first metal cover.

20. The method of claim 17, wherein the metal enclosure comprises at least one member selected from a group consisting of oxygen-free high thermal conductivity copper, electrolytic tough pitch copper, gold, and silver, and wherein the superconducting material has a thickness greater than a penetration depth of the magnetic field.
